(19) United States
(12) Patent Application Publication
(10) Pub. No.: US 2008/0012143 A1
(43) Pub. Date: Jan. 17, 2008

(54) Semiconductor Device and Method of Fabricating the Same

(76) Inventor: JIN HA PARK, Echeon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/776,991

(22) Filed: Jul. 12, 2007

(30) Foreign Application Priority Data
Jul. 12, 2006 (KR) 10-2006-0065399

(51) Int. Cl. H01L 23/48; H01L 21/44

(52) U.S. Cl. 257/763; 438/656; 257/E23.01; 257/E21.476

(57) ABSTRACT

A method of fabricating a semiconductor device can include forming a first metal layer on a semiconductor substrate, and forming a second metal layer on the first metal layer. The second metal layer is ion-implanted with material having an anti-reflective function. The anti-reflective function is endowed to the metal layer using the ion implantation, and a separate anti-reflective layer is not necessary.

### CROSS-REFERENCE TO RELATED APPLICATION

The present application claims the benefit under 35 U.S.C. §119 of Korean Patent Application No. 10-2006-0065399, filed on Jul. 12, 2006, which is hereby incorporated by reference in its entirety.

### BACKGROUND

In general, when word lines, bit lines, or metal interconnections are formed in a process of fabricating a semiconductor device, a material such as silicide or aluminum is often used. However, silicide and aluminum have a very high reflectivity.

Recently, with the high integration of semiconductor devices, topology has been deepened. In particular, the topology is even more deepened between a cell region and a peripheral circuit region. Thus, when a conductive layer required for the device is to be formed using a conductive material having high reflectivity, the deepened topology makes it difficult to obtain a good cross section shape through a patterning process.

In order to solve this reflectivity related problem, an anti-reflective coating (ARC) layer having low reflectivity is formed on a conductive material in the related art. The ARC layer can be made of, for example, TiN, organic bottom anti-reflective coating (BARC), inorganic BARC, or the like.

FIG. 1 is a schematic view illustrating a related semiconductor device.

As illustrated in FIG. 1, a metal layer 3 for forming a metal pattern is formed on a semiconductor substrate 1. Before the metal layer 3 is formed, a series of elements (e.g. transistor, logic circuit, etc.) can be formed.

An ARC layer 5 is formed on the metal layer 3.

Although not illustrated, a photoresist is coated on the ARC layer 5, and then an exposure process is performed to form a desired pattern. An etch process is performed using the patterned photoresist as a mask, thereby etching the ARC layer 5 and the metal layer 3 to form a desired metal pattern. Afterwards, the patterned photoresist and the ARC layer 5 are removed.

This related semiconductor device requires a process of separately forming the ARC layer 5 on the metal layer 3, so that the number and time for the processes are increased, and the cost for the processes is also increased.

The related semiconductor device is not suitable for sub-180 nm semiconductor devices, because reflectivity N and absorptivity K of the ARC layer are fixed. Here, the reflectivity N represents a characteristic for reflecting light, and the absorptivity K represents a characteristic for absorbing light.

### BRIEF SUMMARY

Accordingly, embodiments provide a semiconductor device having an anti-reflective coating (ARC) layer, where the reflectivity N and absorptivity K of which are adjusted to have an optimal characteristic, and a method of fabricating the same.

An embodiment is directed to a semiconductor device and method of fabricating the same, capable of simplifying processes.

According to an embodiment, a method of fabricating a semiconductor device comprises forming a first metal layer on a semiconductor substrate, forming a second metal layer on the first metal layer, and performing ion implantation on the second metal layer. Here, the second metal layer is endowed with an anti-reflective function by the ion implantation.

According to a second embodiment, a semiconductor device comprises a first metal layer on a semiconductor substrate, and a second metal layer having an anti-reflective function on the first metal layer.

### BRIEF DESCRIPTION OF THE DRAWINGS

FIG. 1 is a schematic view illustrating a related semiconductor device; and

FIGS. 2A through 2D are views illustrating a method of fabricating a semiconductor device according to an embodiment.

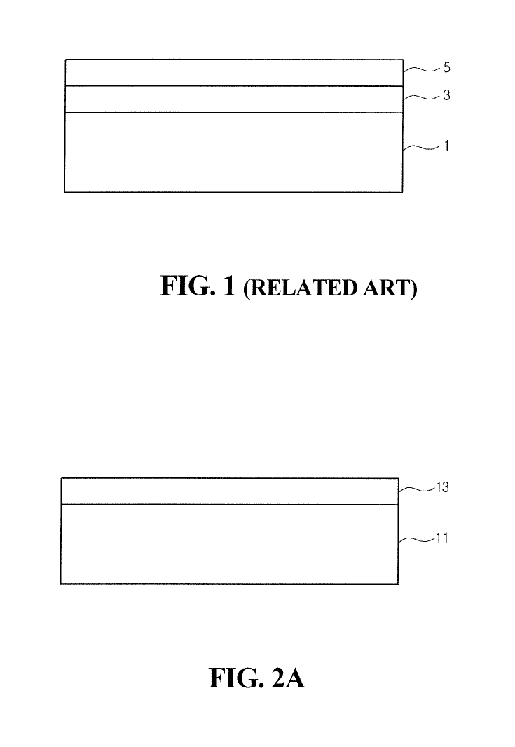

### DETAILED DESCRIPTION

Hereinafter, embodiments of the present invention will be described in detail with reference to the accompanying drawings.

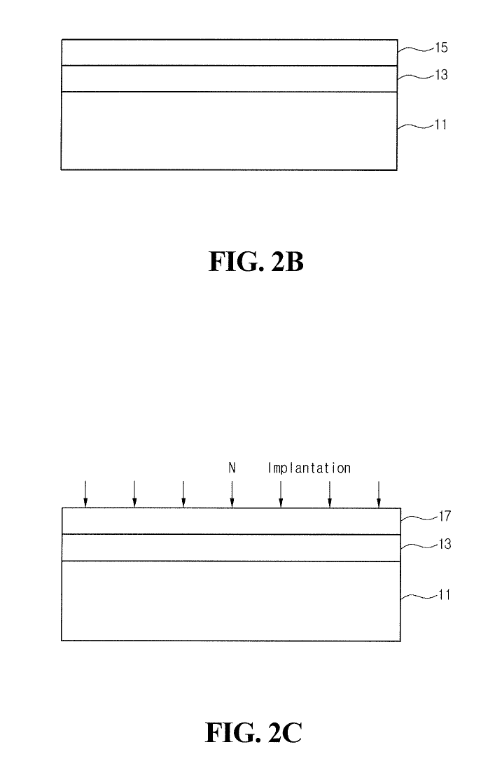

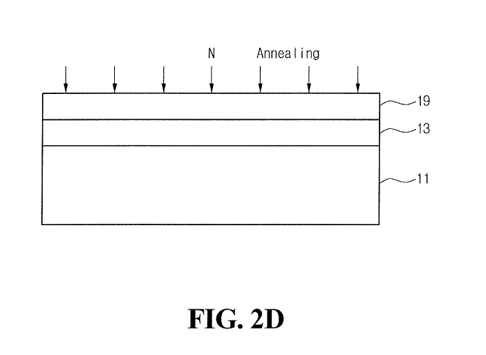

FIGS. 2A through 2D are views illustrating a method of fabricating a semiconductor device according to an embodiment.

As illustrated in FIGS. 2A and 2B, a first metal layer 13 is formed on a semiconductor substrate 11. Then, a second metal layer 15 is formed on the first metal layer 13.

The first metal layer 13 can be made of aluminum (Al), and the second metal layer 15 can be made of titanium (Ti). The first and second metal layers 13 and 15 can be deposited by a sputtering process.

As illustrated in FIG. 2C, an ion implantation process is performed on the second metal layer 15 to implant a predetermined dose of ions into the second metal layer 15. A reference number 17 represents the ion-implanted second metal layer.

The ion implantation process can be performed under conditions of: dopant of nitrogen (N), energy of 5 KeV to 30 KeV, and dose (ion/cm²) of 1E13 to 1E16. In this case, reflectivity N and absorptivity K of the second metal layer 15 can be adjusted by changing a magnitude of energy and an amount of dose. Thereby, the material of the second metal layer 15 is changed from Ti into TiN.

Generally, nitrogen (N) is widely known as a material having low reflectivity N. As described above, the second metal layer 15 made of titanium (Ti) is implanted with the dopant of nitrogen (N) at the energy of 5 KeV to 30 KeV to the dose (ion/cm²) of 1E13 to 1E16, thereby being changed into TiN. In this case, the second metal layer 17 includes TiN. The second metal layer 17 can be used as a metal pattern as well as an ARC layer.

Therefore, unlike a related art of forming the ARC layer of, for example, TiN through a separate process, an ion implantation process can be performed on the second metal layer 15 so as to have a function of a metal pattern as well as the ARC layer. Thus, embodiments of the present invention do not require a separate process for depositing the ARC layer like the related art, so that the number and time for the processes can be decreased, and the cost for the processes can be decreased.

Further, an ARC layer can be formed where the reflectivity N and absorptivity K of which are adjusted to have an optimal characteristic by changing the magnitude of energy and the amount of dose, so that the metal pattern can be optimally formed in a post process.

An embodiment can endow an anti-reflective function to the second metal layer through the ion implantation process. However, because the ion implantation process forcibly implants the dopant, the second metal layer has a possibility of characteristics thereof being deteriorated.

For this reason, as illustrated in FIG. 2D, a rapid thermal processing (RTP) annealing process can be performed on the ion implanted second metal layer 17. That is, the RTP annealing process can be performed under the following conditions in order to supplement the second metal layer 17 with nitrogen (N) and simultaneously stabilize the second metal layer 17. The annealed second metal layer is indicated by a reference number 19.

The conditions of an embodiment of the RTP annealing process are as follows: nitrogen (N), pressure of 760 Torr to 800 Torr, temperature of 300° C. to 500° C., and flow rate of 1 slm to 10 slm. The RTP annealing process can be performed by supplying nitrogen (N) to the second metal layer 17 at the flow rate of 1 slm to 10 slm at the temperature of 300° C. to 500° C. under the pressure of 760 Torr to 800 Torr.

In this case, reflectivity N and absorptivity K of the second metal layer 17 can be adjusted by changing the flow rate and the temperature.

This RTP annealing process can compensate for the ion implanted dose described with respect to FIG. 2C and stabilizes an equilibrium state of the second metal layer 17.

Although not illustrated, a photoresist is coated on the annealed second metal layer 19, and then an exposure process is performed to form a desired pattern. An etch process is performed using the patterned photoresist as a mask, thereby etching the first and second metal layers 13 and 19 to form a desired metal pattern. Afterwards, the patterned photoresist is removed.

As described above, an anti-reflective function can be endowed to the second metal layer through the ion implantation process.

An embodiment not only provides the anti-reflective function to the second metal layer using the ion implantation process and the RTP annealing process, but also enables the second metal layer to make up for the insufficient dopant after the ion implantation and to have the optimal reflective characteristic.

Further, an embodiment can endow the anti-reflective function to the metal layer using an ion implantation process. As a result, it is not necessary to form a separate anti-reflective layer. Therefore, embodiments can reduce the number, time, and cost for the processes.

In addition, an ion implantation process and an RTP annealing process can be performed on the metal layer, so that an anti-reflective function having optimal reflective characteristics can be endowed to the metal layer, and the number, time, and cost for the processes may be reduced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device, the method comprising:
forming a first metal layer on a semiconductor substrate;
forming a second metal layer on the first metal layer; and
performing ion implantation on the second metal layer,
wherein the ion implantation endows the second metal layer with an anti-reflective function.

2. The method according to claim 1, wherein the ion implantation is performed under conditions of: dopant of nitrogen (N), energy of 5 KeV to 30 KeV, and dose (ion/cm²) of 1E13 to 1E16.

3. The method according to claim 2, further comprising adjusting reflectivity and absorptivity of the second metal layer by changing a magnitude of energy and an amount of dose of the ion implantation.

4. The method according to claim 1, wherein the first metal layer comprises aluminum (Al).

5. The method according to claim 1, wherein the second metal layer comprises titanium (Ti).

6. The method according to claim 1, further comprising:
annealing the ion-implanted second metal layer.

7. The method according to claim 6, wherein the annealing is performed under conditions of: gas of nitrogen (N), pressure of 760 Torr to 800 Torr, temperature of 300° C. to 500° C., and flow rate of 1 slm to 10 slm.

8. The method according to claim 6, further comprising adjusting reflectivity and absorptivity of the annealed second metal layer by changing a magnitude of energy and an amount of dose of the ion implantation.

9. The method according to claim 6, wherein the annealing is performed by rapid thermal processing (RTP).

10. A semiconductor device comprising:
a first metal layer on a semiconductor substrate; and
a second metal layer having an anti-reflective function on the first metal layer.

11. The semiconductor device according to claim 10, wherein the second metal layer comprises titanium and nitrogen.

12. The semiconductor device according to claim 11, wherein the nitrogen provides the anti-reflective function of the second metal layer.

13. The semiconductor device according to claim 10, wherein the second metal layer comprises an ion-implanted second metal layer, wherein the ions implanted in the second metal layer provide the anti-reflective function.
